(19) United States
(12) Patent Application Publication
(10) Pub. No.: US 2021/0191477 A1
(43) Pub. Date: Jun. 24, 2021

(54) DISPLAY DEVICE

(71) Applicant: SHARP KABUSHIKI KAISHA, Osaka (JP)

(72) Inventors: SHINJI YAMAGISHI, Osaka (JP); KAZUTOSHI KIDA, Osaka (JP); TAKENORI MARUYAMA, Osaka (JP); TAKUMA YAMAMOTO, Osaka (JP); Jean de Dieu B. MUGIRANEZA, Osaka (JP); YASUHIRO SUGITA, Osaka (JP); HIROSHI FUKUSHIMA, Osaka (JP)

(21) Appl. No.: 17/122,903

(22) Filed: Dec. 15, 2020

(30) Foreign Application Priority Data
Dec. 19, 2019 (JP) 2019-229643

(51) Int. Cl. G06F 1/16

(52) U.S. Cl. CPC G06F 1/1698; G02F 1/136286

(57) ABSTRACT

A display device includes a display unit including a pixel circuit, an antenna including at least one antenna element that is flat, a noise barrier plate made of metal or magnetic substance, and a casing having a bottom made of metal or resin. The at least one antenna element is disposed under the display unit, the noise barrier plate is disposed under the at least one antenna element, and the bottom is disposed under the noise barrier plate, where a direction for the display unit to display an image is defined as an upper side, where another direction opposite to the direction is defined as a lower side.

### CROSS-REFERENCE TO RELATED APPLICATION

The present application claims priority from Japanese Application JP2019-229643, the content of which is hereby incorporated by reference into this application.

### BACKGROUND ART

### Technical Field

The disclosure relates to a display device that includes an antenna for reading a communication medium, such as an integrated circuit (IC) card.

### Description of the Background Art

A recent study addresses installing an antenna for short-range wireless communication (e.g., NFC or near-field communication) on a display device. Unfortunately, upon voltage signal application to pixel circuits included in a display unit, such a display device generates noise that affects the communication performance of its antenna, thus degrading the antenna communication performance.

Japanese Patent Application Laid-Open No. 2016-143971, for instance, proposes a display device that includes an adjuster for reducing the influence of noise generated from its display unit on antenna communication.

### SUMMARY

Other than display devices, such as television sets, a display device with an antenna is applicable to small and thin display devices, such as watches and mobile terminals. However, the display unit and antenna get closer to each other along with decrease in the size and thickness of the display device, and the noise from the display unit greatly affects antenna communication. This considerably degrades the communication performance of the antenna. In the display device in Japanese Patent Application Laid-Open No. 2016-143971 for instance, size and thickness reduction causes such an unstable reading of a communication medium (e.g., an IC card) as to hinder user use.

To solve this problem, it is an object of the disclosure to provide a small and thin display device capable of preventing reduction in the communication performance of its antenna.

To solve the problem, a first aspect of the disclosure provides a display device that includes that following: a display unit including a pixel circuit; an antenna including at least one antenna element that is flat; a noise barrier plate made of metal or magnetic substance; and a casing having a bottom made of metal or resin. The at least one antenna element is disposed under the display unit, the noise barrier plate is disposed under the at least one antenna element, and the bottom is disposed under the noise barrier plate, where a direction for the display unit to display an image is defined as an upper side, where another direction opposite to the direction is defined as a lower side.

The above configuration offers a small and thin display device capable of preventing reduction in the communication performance of its antenna to such an extent as not to hinder user use.

### BRIEF DESCRIPTION OF THE DRAWINGS

FIG. 1 is a schematic cross-sectional view of the configuration of a display device 1 according to a first preferred embodiment;

FIG. 2 is a plan view of the arrangement of an antenna 20 and a noise barrier plate 30 included in the display device 1 according to the first preferred embodiment;

FIG. 3 is a schematic cross-sectional view of the configuration of main components of a display device 1A according to a second preferred embodiment;

FIG. 4 is a plan view of the arrangement of an antenna 20A and the noise barrier plate 30 included in the display device 1A according to the second preferred embodiment;

FIG. 5 is a plan view of another example configuration of the antenna included in the display device according to the second preferred embodiment;

FIG. 6 is a block diagram illustrating an example configuration of main components of a display device according to a third preferred embodiment; and

FIG. 7 is a graph illustrating an example operation of the display device according to the third preferred embodiment.

### DETAILED DESCRIPTION OF THE DISCLOSURE

With reference to the accompanying drawings, preferred embodiments of the disclosure will be detailed. Identical or equivalent components in the drawings will be denoted by the same signs and will not be elaborated upon. For easy description, the accompanying drawings show simplified or schematic configurations, and omit some of the components. The dimensional ratio between the components in each of the accompanying drawings is not necessarily equal to the actual dimensional ratio.

Each preferred embodiment of the disclosure describes a liquid-crystal display by way of example. Nevertheless, the disclosure is not limited to a liquid-crystal display and is also applicable to other kinds of display device, including an organic electro-luminescence (EL) display.

### First Preferred Embodiment

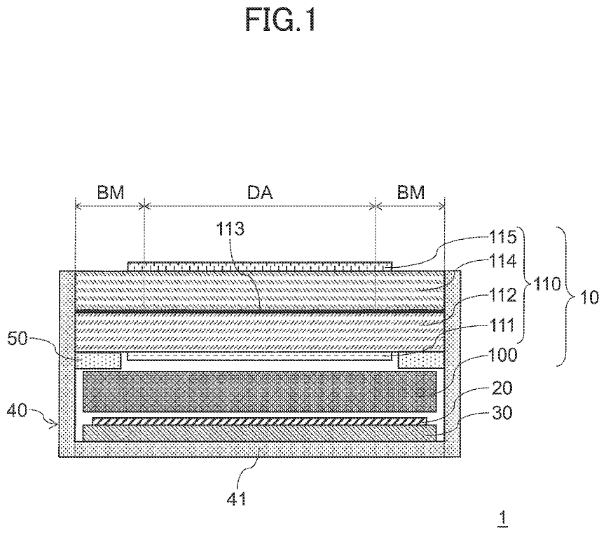

FIG. 1 is a schematic cross-sectional view of the configuration of a display device 1 according to a first preferred embodiment. The display device 1 includes a display unit 10, an antenna 20, a noise barrier plate 30, a casing 40, and a rim sheet 50, as illustrated in FIG. 1.

The display unit 10 is composed of an image display component, such as a liquid-crystal display module. The display unit 10 includes a backlight 100 and a liquid-crystal panel 110. The liquid-crystal panel 110 has a stack of, in sequence, a lower polarizer plate 111, a lower substrate 112, a liquid-crystal layer 113, an upper substrate 114, an upper polarizer plate 115. In the following description, a direction where the liquid-crystal panel 110 is located when viewed from the backlight 100 (i.e., a direction where the display unit 10 displays an image) is defined as the upper side of the display device 1, and the opposite direction is defined as the lower side of the same.

The backlight 100 emits planar light upward. The backlight 100 includes a light source (e.g., LEDs or light-emitting diodes) and a light-guiding plate that diffuses, in a planar manner, light emitted from the light source, and radiates the light upward. For instance, the backlight 100 includes LEDs on the side of the light-guiding plate, and includes a reflective plate under the light-guiding plate. The lower polarizer plate 111 selectively transmits a component contained in light from the backlight 100 and oscillating in a first direction.

The liquid-crystal layer 113 is disposed between the lower substrate 112 and the upper substrate 114. The lower substrate 112 includes pixel circuits (e.g., TFTs or thin film transistors) for voltage application to liquid crystals within the liquid-crystal layer 113. These liquid crystals change their orientation according to applied voltage, and this orientation controls the direction of oscillation of light passing through the liquid-crystal layer 113.

The upper substrate 114 has a color filter that selectively transmits components contained in light passing through the liquid-crystal layer 113, and having particular wavelength bands (colors). For instance, the color filter has a predetermined pattern of arrangement (e.g., a stripe arrangement and a mosaic arrangement) composed of a filter that transmits red light, a filter that transmits green light, and a filter that transmits blue light. The color filter is disposed in a display region DA, the outside of which is a black matrix region BM provided with a light blockage filter. The upper polarizer plate 115 selectively transmits a component contained in each color of light passing through the color filter of the upper substrate 114, and oscillating in a second direction.

When the first and second directions are perpendicular for instance, upon change in the direction of oscillation caused by the liquid crystals, light passing through the lower polarizer plate 111 and oscillating in the first direction has increased components that oscillate in the second direction. Such a change in the oscillation direction caused by the liquid crystals allows the light passing through the lower polarizer plate 111 to pass through the upper polarizer plate 115. On the other hand, the light passing through the lower polarizer plate 111 and oscillating in the first direction is blocked by the upper polarizer plate 115 unless the oscillation direction is changed by the liquid crystals.

When the first and second directions are parallel for instance, upon change in the direction of oscillation caused by the liquid crystals, light passing through the lower polarizer plate 111 and oscillating in the first direction has decreased components that oscillate in the second direction. Such a change in the oscillation direction caused by the liquid crystals causes the light passing through the lower polarizer plate 111 to be blocked by the upper polarizer plate 115. On the other hand, the light passing through the lower polarizer plate 111 and oscillating in the first direction passes through the upper polarizer plate 115 unless the oscillation direction is changed by the liquid crystals.

As described above, the display unit 10 controls the alignment direction of the liquid crystals by regulating voltage applied to the liquid crystals, and controls light passing through the upper polarizer plate 115. This enables the display unit 10 to display an image.

The antenna 20 is used for short-range wireless communication, and communicates with a communication medium (e.g., an IC card) brought close to the upper surface of the display unit 10 (i.e., an image display surface). The antenna 20 is disposed under the display unit 10.

The noise barrier plate 30 is made of metal or magnetic substance, and is disposed under the antenna 20. The noise barrier plate 30 reduces the influence of noise generated from the display unit 10, when the antenna 20 communicates with a communication medium. For instance, the noise barrier plate 30 is made of ferrite magnetic substance containing an iron oxide.

The casing 40 is a box having an open upper side, and houses the display unit 10, the antenna 20, the noise barrier plate 30, and the rim sheet 50. The casing 40 has a bottom 41 disposed under the noise barrier plate 30 and made of metal or resin. It is noted that parts of the casing 40 other than the bottom 41 may be also made of the same metal or resin as the bottom 41. It is also noted that for metal, the casing bottom 41 is preferably formed using a low-conductivity metal, such as stainless steel, in order to reduce noise influence. It is also noted a small and thin display device (e.g., a watch and a mobile terminal) requires a thin and sufficiently strong casing 40; hence, the bottom 41 and by extension the casing 40 are preferably made of stainless steel.

The rim sheet 50 is disposed between the backlight 100 and the liquid-crystal panel 110 and outside the display region DA. The rim sheet 50 is made of, for instance, elastic resin, and functions as a buffer and a waterproof material.

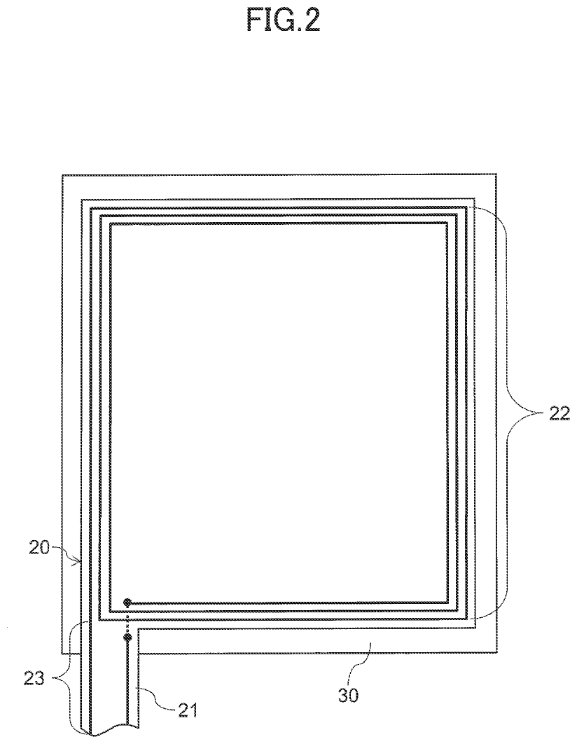

FIG. 2 is a plan view of the arrangement of the antenna 20 and noise barrier plate 30 included in the display device 1 according to the first preferred embodiment. FIG. 2 is a plan view of the display unit 10 viewed from above, and shows only the antenna 20 and the noise barrier plate 30.

The antenna 20 includes a flexible printed circuit (FPC) board 21, an antenna element 22, and two feeder lines 23, as illustrated in FIG. 2. The antenna element 22 and the feeder lines 23 are disposed on the FPC board 21. The antenna element 22 is flat and composed of, for instance, a loop antenna, a helical antenna, or a spiral antenna. Each feeder line 23 is connected to the antenna element 22 and transmits a signal that is sent and received via the antenna element 22.

When the antenna element 22 is composed of a multi-turn loop antenna, as illustrated in FIG. 2 for instance, one of the feeder lines 23 is connected to one end of the antenna element 22 and the other feeder line 23 is connected to the other end of the antenna element 22. In this case, the end of the antenna element 22 wound inside and the feeder line 23 may be connected together on the FPC board 21 to which an element, a wire, and other things are attached externally.

Alternatively, the FPC board 21 may be formed to have a multi-layer structure (e.g., a structure with conductors on both surfaces), in which the end of the antenna element 22 and the feeder line 23 may be connected together via a wire provided in a layer where the antenna element 22 and the feeder line 23 are not located.

As illustrated in FIG. 2, the entire antenna element 22 is disposed on the noise barrier plate 30 in a plan view when the display unit 10 is viewed from above. That is, the antenna element 22 is encompassed by the noise barrier plate 30 in this plan view.

As described above, the display device 1 includes the antenna element 22 under which the noise barrier plate 30 and the bottom 41 are disposed. The noise barrier plate 30 is made of metal or magnetic substance, and the bottom 41 is made of metal or resin. This configuration enables the display device 1 that is small and thin to prevent reduction in the communication performance of the antenna 20 to such an extent as not to hinder user use.

In particular, the noise barrier plate 30, which is made of ferrite magnetic substance, and the bottom 41 of the casing 40, which is made of stainless steel, can achieve a synergistic effect of noise prevention, thus effectively preventing reduction in the communication performance of the antenna 20.

It is noted that the entire antenna element 22 does not necessarily have to be disposed on the noise barrier plate 30 in a plan view when the display unit 10 is viewed from above. However, to sufficiently prevent reduction in the antenna communication performance, more than a half of the antenna element 22 is preferably disposed on the noise barrier plate 30 in this plan view. Placing the entire antenna element 22 on the noise barrier plate 30 in a plan view when the display unit 10 is viewed from above can minimize reduction in the antenna communication performance.

### Second Preferred Embodiment

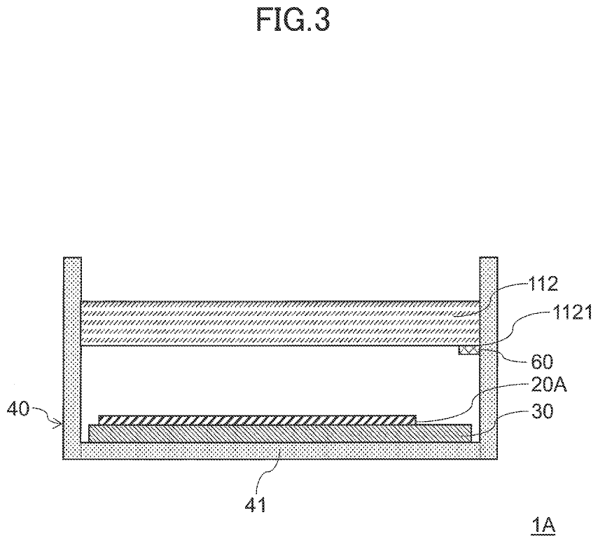

A second preferred embodiment will be described. FIG. 3 is a schematic cross-sectional view of the configuration of main components of a display device 1A according to the second preferred embodiment. FIG. 3 shows only the lower substrate 112, an antenna 20A, the noise barrier plate 30, the casing 40, and a source driver 60. The source driver 60 is electrically connected to pixel circuits at an end 1121 of the lower substrate 112, and inputs, to the pixel circuits, a voltage signal having a level corresponding to image data.

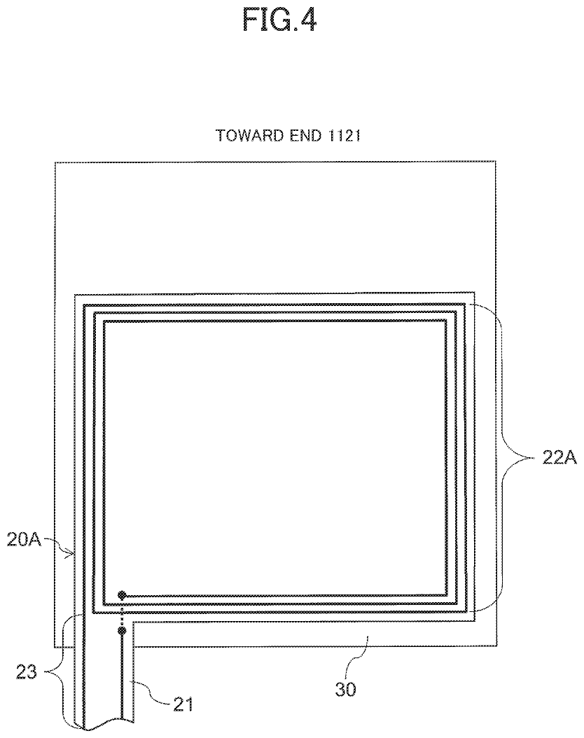

FIG. 4 is a plan view of the arrangement of the antenna 20A and noise barrier plate 30 included in the display device 1A according to the second preferred embodiment. FIG. 4 is a plan view of the display unit 10 viewed from above, and shows only the antenna 20A and the noise barrier plate 30.

The antenna 20A is spaced away from the end 1121 of the lower substrate 112, as illustrated in FIGS. 3 and 4. To be specific, the antenna 20A includes an antenna element 22A spaced away from the end 1121 of the lower substrate 112 by equal to or more than 10 mm in a plan view when the display unit 10 is viewed from above.

A diligent study conducted by the inventors has demonstrated that preventing reduction in the communication performance of the antenna 20A requires the antenna element 22A to be spaced away not from the source driver 60 per se, but from the end 1121 of the lower substrate 112, which is electrically connected to the source driver 60. In addition, placing the antenna element 22A away from the end 1121 of the lower substrate 112 by equal to or more than 10 mm in a plan view when the display unit 10 is viewed from above, can effectively prevent reduction in the communication performance of the antenna 20A.

For instance, the source driver 60 can be mounted on an FPC board, and the FPC board can be connected to the end 1121 of the lower substrate 112; in this case, the antenna element 22A still needs to be spaced away from the end 1121, which is connected to the FPC board.

In some cases, the feeder lines 23 need to be placed so as to extend from the antenna element 22A toward the end 1121, unlike the example in FIG. 4; accordingly, the feeder lines 23 are affected by noise, thus possibly degrading the communication performance. In extending the feeder lines 23 toward the end 1121, it is accordingly preferable that the feeder lines 23 be designed to be less susceptible to noise.

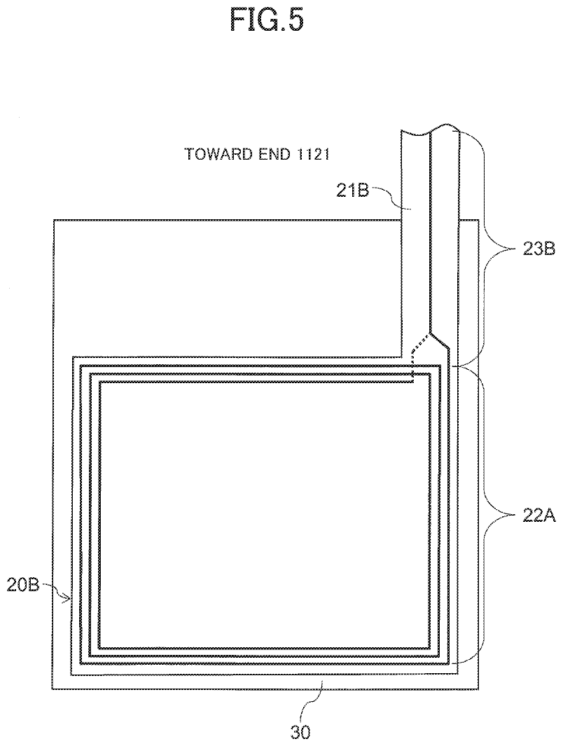

FIG. 5 is a plan view of another example configuration of the antenna included in the display device according to the second preferred embodiment. FIG. 5 is similar to FIG. 4. FIG. 5 shows an antenna 20B that includes the FPC board 21 having a multi-layer structure (e.g., a structure with conductors on both surfaces). FIG. 5 also shows two feeder lines 23B overlapping each other in a plan view when the display unit 10 is viewed from above. Such two feeder lines 23B, which are supplied with reverse current to cancel out a magnetic field, can be less susceptible to noise.

### Third Preferred Embodiment

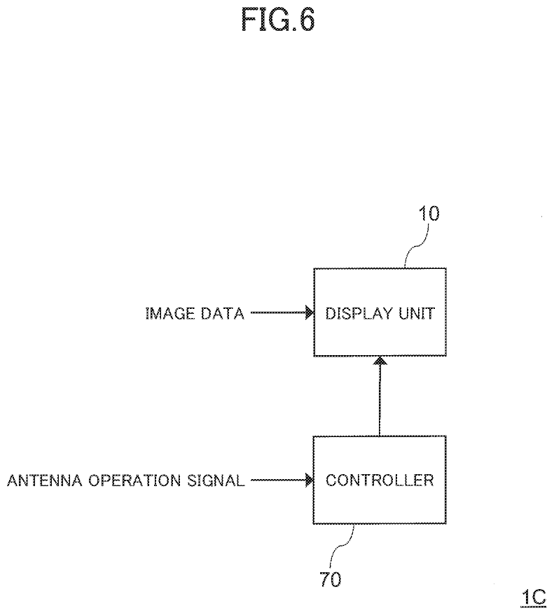

A third preferred embodiment will be described. FIG. 6 is a block diagram illustrating an example configuration of main components of a display device according to a third preferred embodiment. FIG. 6 shows a display device 1C that includes a controller 70 that controls the operation of the display unit 10.

The controller 70 is composed of, for instance, a computing unit (e.g., a CPU or central processing unit) and a recording unit (e.g., a semiconductor memory). The controller 70 controls the operation of the display unit 10 on the basis of an antenna operation signal indicating whether an antenna communicates with a communication medium.

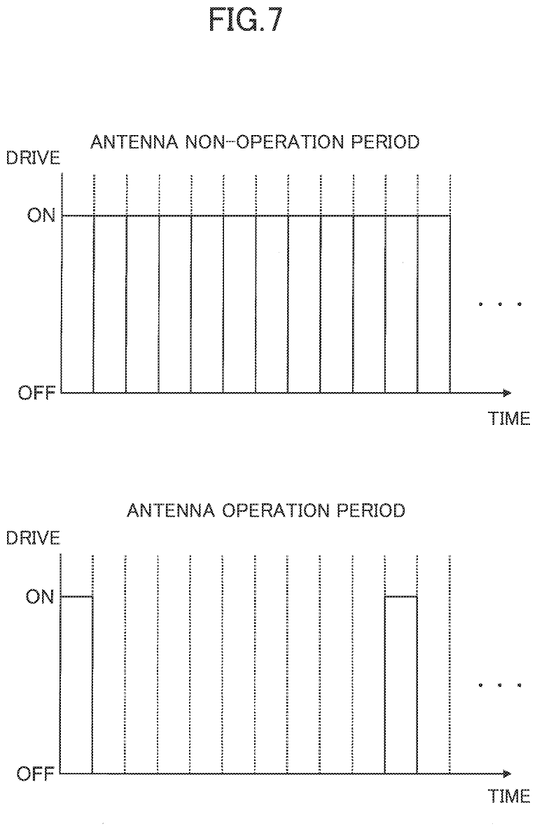

FIG. 7 is a graph illustrating an example operation of the display device according to the third preferred embodiment. The lateral axis of the graph represents time, and the longitudinal axis of the graph represents whether pixel circuits are driven. The drive of the pixel circuits refers to applying, to the pixel circuits, a voltage signal corresponding to image data. In FIG. 7, ON represents that the pixel circuits are driven, and OFF represents that the pixel circuits are not driven. Thus in FIG. 7, the number of times of switch to ON per unit time corresponds to the refresh rate of the display unit 10. FIG. 7 also shows a comparison between an antenna non-operation period, during which the antenna does not communicate with the communication medium, and an antenna operation period, during which the antenna communicates with the communication medium.

The controller 70 sets the refresh rate of the display unit 10 in the antenna operation period to be smaller than the refresh rate in the antenna non-operation period, as illustrated in FIG. 7. For instance, the controller 70 sets the refresh rate of the display unit 10 in the antenna non-operation period to be 60 Hz, and sets the refresh rate of the same in the antenna operation period to be equal to or less than 10 Hz.

The number of times of voltage signal input to the pixel circuits decreases along with decrease in the refresh rate of the display unit 10. This reduces the number of times of noise generation from the display unit 10 per unit time. Accordingly, setting the refresh rate of the display unit 10 in the antenna operation period to be smaller than the refresh rate of the display unit 10 in the antenna non-operation period can prevent reduction in the communication performance of the antenna communicating with the communication medium.

In particular, the display unit 10 having a drawing rate of 10 Hz or less per unit time in the antenna operation period can sufficiently prevent reduction in the antenna communication performance.

A reduction in the refresh rate causes the pixel circuits to hold accumulated charges for a long time, during which current leakage changes liquid-crystal alignment, possibly degrading image quality.

The controller 70 may accordingly control the display unit 10 to display a simple image including only characters, such as “Hold the card over here”, in the antenna operation period. The controller 70 controls the display unit 10 in such a manner. This enables image quality degradation resulting from a lowered refresh rate to be less recognized by a user.

The pixel circuits may be formed using an oxide semiconductor. An example of the oxide semiconductor is an In—Ga—Zn—O semiconductor (e.g., indium gallium zinc oxide). The In—Ga—Zn—O semiconductor is a ternary oxide of indium (In), gallium (Ga), and zinc (Zn); the ratio (compositional ratio) between In, Ga, and Zn may be expressed as, for instance, In:Ga:Zn=2:2:1, In:Ga:Zn=1:1:1, or In:Ga:Zn=1:1:2.

A pixel circuit of oxide semiconductor can offer an extremely smaller leakage current than a pixel circuit of amorphous silicon or other materials. For instance, a pixel circuit of In-Ga—Zn—O semiconductor can offer a smaller leakage current than a pixel circuit of amorphous silicon by less than one hundredth. A pixel circuit of oxide semiconductor, by extension, of In-Ga—Zn—O semiconductor enables image quality degradation resulting from a lowered refresh rate in the antenna operation period to be less recognized by the user.

The pixel circuits may be formed using an oxide semiconductor other than an In-Ga—Zn—O semiconductor. The circuits may include, for instance, an In—Sn—Zn—O semiconductor (e.g., In₂O₃—SnO₂—ZnO, InSnZnO) The In—Sn—Zn—O semiconductor is a ternary oxide of indium (In), tin (Sn), and zinc (Zn). Alternatively, the pixel circuits may be formed using an oxide semiconductor, including an In—Al—Zn—O semiconductor, an In-AI-Sn—Zn—O semiconductor, a Zn—O semiconductor, an In—Zn—O semiconductor, a Zn—Ti—O semiconductor, a Cd—Ge—O semiconductor, a Cd—Pb—O semiconductor, CdO or cadmium oxide, a Mg—Zn—O semiconductor, an In—Ga—Sn—O semiconductor, an In—Ga—O semiconductor, a Zr—In—Zn—O semiconductor, and a Hf—In—Zn—O semiconductor.

Modifications and Others

The foregoing preferred embodiments are mere examples for implementing the disclosure. The disclosure is thus not limited to the foregoing preferred embodiments; various modifications can be devised, as appropriate, without departing from the scope of the disclosure.

In the first and second preferred embodiments for instance, the FPC board 21 may have a multi-layer structure (e.g., a structure with conductors on both surfaces); in addition, a plurality of antenna elements 22, 22A, and 22B may be provided so as to overlap each other in a plan view when the display unit 10 is viewed from above, to thus establish electrical connection. In this case, near a location of connection with the feeder lines 23 for instance, the antenna elements 22, 22A, and 22B may be in contact with each other within the FPC board 21 to establish electrical connection.

Such a configuration, which includes a parallel arrangement of the antenna elements 22, 22A, and 22B, can reduce resistance. Thus, elongating the antenna elements 22, 22A, and 22B can improve antenna communication performance. For instance, a multi-turn loop antenna with increased turns can improve the communication performance. Moreover, reducing the resistances of the antenna elements 22, 22A, and 22B enables the antenna elements 22, 22A, and 22B to have a narrow wire width. This enables the antenna elements 22, 22A, and 22B and the antennas 20, 20A, and 20B to be downsized.

The first to third preferred embodiments can be implemented independently or in combination with any preferred embodiment.

The display devices can be described as below.

A first aspect provides a display device that includes the following: a display unit including a pixel circuit; an antenna including at least one antenna element that is flat; a noise barrier plate made of metal or magnetic substance; and a casing having a bottom made of metal or resin. The at least one antenna element is disposed under the display unit, the noise barrier plate is disposed under the at least one antenna element, and the bottom is disposed under the noise barrier plate, where a direction for the display unit to display an image is defined as an upper side, where another direction opposite to the direction is defined as a lower side. This configuration offers a small and thin display device capable of preventing reduction in the communication performance of its antenna to such an extent as not to hinder user use.

A second aspect provides that in the first aspect, the noise barrier plate may be made of ferrite magnetic substance containing an iron oxide, and the bottom may be made of stainless steel. This configuration can achieve a synergistic effect of noise prevention, thus effectively preventing reduction in the antenna communication performance.

A third aspect provides that in the first or second aspect, more than a half of the at least one antenna element may be disposed on the noise barrier plate in a plan view when the display unit is viewed from above. This configuration can sufficiently prevent reduction in the antenna communication performance.

A fourth aspect provides that in the third aspect, the entire at least one antenna element may be disposed on the noise barrier plate in the plan view. This configuration can minimize reduction in the antenna communication performance.

A fifth aspect provides that in any one of the first to fourth aspects, the at least one antenna element may include a plurality of antenna elements electrically connected together, and the plurality of antenna elements may overlap each other in a plan view when the display unit is viewed from above. This configuration, which includes a parallel arrangement of the antenna elements, can reduce resistance. Thus, elongating the antenna elements can improve the antenna communication performance. In addition, reducing the wire widths of the antenna elements can downsize the antenna.

A sixth aspect provides that in any one of the first to fifth aspects, the display unit may include the following: a substrate on which the pixel circuit is disposed; and a driver element electrically connected to the pixel circuit at an end of the substrate. The driver element inputs, to the pixel circuit, a voltage signal having a level corresponding to image data. The at least one antenna element may be spaced away from the end by equal to or more than 10 mm in a plan view when the display unit is viewed from above. This configuration can effectively prevent reduction in the antenna communication performance.

A seventh aspect provides that in the sixth aspect, the antenna may include two feeder lines connected to the at least one antenna element, and in the plan view, the two feeder lines may extend from the at least one antenna element toward the end and overlap each other. In this configuration, the two feeder lines, which are supplied with reverse current to cancel out a magnetic field, can be less susceptible to noise.

An eighth aspect provides that the display device in any one of the first to seventh aspects may further include a controller that controls the refresh rate of the display unit. The controller may set the refresh rate in a period during which the antenna communicates with a communication medium to be smaller than the refresh rate in a period during which the antenna does not communicate with the communication medium. This configuration can prevent reduction in the communication performance of the antenna communicating with the communication medium.

A ninth aspect provides that in the eighth aspect, the controller may set the refresh rate in the period during which the antenna communicates with the communication medium to be equal to or less than 10 Hz. This configuration can sufficiently prevent reduction in the antenna communication performance.

A tenth aspect provides that in the eighth or ninth aspect, the pixel circuit may be made of oxide semiconductor. Furthermore, an eleventh aspect provides that in the tenth aspect, the pixel circuit may be made of In-Ga—Zn—O oxide semiconductor. This configuration enables image quality degradation resulting from a lowered refresh rate to be less recognized by a user when the antenna communicates with the communication medium.

What is claimed is:

1. A display device comprising:
a display unit including a pixel circuit;
an antenna including at least one antenna element that is flat;
a noise barrier plate comprising a metal or a magnetic substance; and
a casing having a bottom comprising a metal or a resin,
wherein the at least one antenna element is disposed under the display unit, the noise barrier plate is disposed under the at least one antenna element, and the bottom is disposed under the noise barrier plate, where a direction for the display unit to display an image is defined as an upper side, where another direction opposite to the direction is defined as a lower side.

2. The display device according to claim 1, wherein
the noise barrier plate comprises a ferrite magnetic substance comprising an iron oxide, and
the bottom comprises a stainless steel material.

3. The display device according to claim 1, wherein more than a half of the at least one antenna element is disposed on the noise barrier plate in a plan view when the display unit is viewed from above.

4. The display device according to claim 3, wherein the entire at least one antenna element is disposed on the noise barrier plate in the plan view.

5. The display device according to claim 1, wherein
the at least one antenna element comprises a plurality of antenna elements electrically connected together, and
the plurality of antenna elements overlap each other in a plan view when the display unit is viewed from above.

6. The display device according to claim 1, wherein
the display unit includes
a substrate on which the pixel circuit is disposed, and
a driver element electrically connected to the pixel circuit at an end of the substrate, the driver element being configured to input, to the pixel circuit, a voltage signal having a level corresponding to image data, and
the at least one antenna element is spaced away from the end by equal to or more than 10 mm in a plan view when the display unit is viewed from above.

7. The display device according to claim 6, wherein
the antenna includes two feeder lines connected to the at least one antenna element, and
in the plan view, the two feeder lines extend from the at least one antenna element toward the end and overlap each other.

8. The display device according to claim 1, further comprising
a controller configured to control a refresh rate of the display unit,
wherein the controller sets the refresh rate in a period during which the antenna communicates with a communication medium to be smaller than the refresh rate in a period during which the antenna does not communicate with the communication medium.

9. The display device according to claim 8, wherein the controller sets the refresh rate in the period during which the antenna communicates with the communication medium to be equal to or less than 10 Hz.

10. The display device according to claim 8, wherein the pixel circuit comprises an oxide semiconductor.

11. The display device according to claim 10, wherein the pixel circuit comprises an In—Ga—Zn—O oxide semiconductor.
